(19) United States
(12) Patent Application Publication
(10) Pub. No.: US 2026/0282293 A1
(43) Pub. Date: Sep. 17, 2026

(54) COMPOSITIONS OF IMMERSION FLUIDS WITH CONTAMINANTS

(71) Applicant: THE CHEMOURS COMPANY FC, LLC, WILMINGTON, DE (US)

(72) Inventors: GUSTAVO POTTKER, HOCKESSIN, DE (US); DREW RICHARD BRANDT, WEST CHESTER, PA (US); ABIGAIL ROSE VAN WASSEN, MEDIA, PA (US); XUE SHA, AVONDALE, PA (US)

(73) Assignee: THE CHEMOURS COMPANY FC, LLC, WILMINGTON, DE (US)

(21) Appl. No.: 19/474,040

(22) PCT Filed: Jun. 20, 2024
(86) PCT No.: PCT/US2024/034654

§ 371 Date: Oct. 9, 2025

Related U.S. Application Data
(60) Provisional application No. 63/522,317, filed on Jun. 21, 2023.

(51) Int. Cl. H05K 7/20; C09K 5/10

(52) U.S. Cl. CPC H05K 7/20809; C09K 5/10

(57) ABSTRACT

Disclosed is a hydrofluoroolefin working fluid including: a dielectric fluid selected from E-HFO-153-10mczz and/or E-HFO-153-10mzzy; and water dissolved within the dielectric fluid at a concentration of from 10 to about 145 ppm of and/or a plasticizer or plasticizer mixture dissolved within the dielectric fluid at a concentration of from about 10 to about 7341 ppm. The hydrofluoroolefin working fluid is useful for immersion cooling of an electronic component.

### FIELD

This invention relates to fluids useful as heat transfer fluids in immersion cooling applications of electrical components.

### BACKGROUND

Immersion cooled server components are known to be very sensitive to the presence of contaminants, such as plasticizers and water. Even small amounts of these contaminants, in values <100 ppm level, can cause potential hardware/server failures, reduction of equipment lifetime or increase in chip temperatures. The formation of deposits, corrosion and dendrites in immersed server parts are some of the potential specific issues described by literature and industry.

Water typically comes from the server parts (which are exposed to moisture before being submerged in the fluid) and also from the surrounding humid air which makes its way to the fluid whenever the immersion tank lid is open. When in solution with the immersion fluid, water can be detrimental to its dielectric properties such as breakdown voltage, dissipation factor (loss tangent) and volume resistivity. When the water concentration is higher than its solubility limit in the dielectric fluid, the excess water becomes “free” and can deposit in parts of the server, potentially causing short circuits and failures. The other issue between water, especially free water, and immersion fluids such as Novec 649 and HFE-7100, is the potential for hydrolysis-chemical breakdown of the immersion fluid- and consequently potential for formation of acids that can attack server parts, cause component failures and reduction of server lifetime.

The other typical contaminants, plasticizers such as DOTP and TOTM, are naturally extracted (or diffused) from components such as cables, elastomers, and plastics by the immersion fluid itself. When in solution, plasticizers can be detrimental to the immersion fluid dielectric properties. When the plasticizer concentration is higher than its solubility limit in the dielectric fluid, the excess plasticizer can deposit on tank or server parts. More specifically, these plasticizers can deposit by distillation in hot surfaces with active boiling. This can be particularly problematic for boiler plates—heat spreader with a porous heat transfer surfaces that sit on top of CPUs and GPUs—in which the plasticizers can deposit and fill bubble nucleation cavities. This reduction in bubble nucleation sites causes reduction in heat transfer performance and consequently increase in the internal chip (“junction”) temperature. Higher junction temperatures can decrease the lifetime of the chip and cause early “throttling” (reduction of processing rate) of the chip to reduce dissipation power when the junction temperature approaches the maximum value established by the chip manufacturer.

When water and/or plasticizers are present in certain immersion fluid, additional chemical reactions can occur, other compounds can be formed and cause additional issues in the server.

In order to mitigate the impact of water, plasticizers and other contaminants, immersion cooling tanks have filtration and desiccant systems. The filtration system typically consists of a pump (or pumps) that circulate the immersion fluid through a filter. Filter materials are typically activated carbon and alumina to capture plasticizers and acids. The more sensitive the immersion fluid to contaminants—i.e., the lower the ppm level of plasticizers it can tolerate before it starts impacting the server reliability—the greater the amount of sorptive media such as activated carbon used and potentially the higher the flow rate of pump(s). More carbon means higher cost and a larger filter housing. A higher flow rate implies a larger pump and higher energy consumption. For removing moisture, typical desiccant materials such as silica gel, molecular sieve and calcium sulfate are used. A fan is used to circulate the mixture of immersion fluid vapor and air through the desiccant material. Like with plasticizers, the more sensitive the immersion fluid to water, the more desiccant material and potentially the bigger the fan necessary, causing increase in cost and energy use. Once desiccant or filter material are saturated, they need to be replaced. The more often it happens, the higher the operating costs.

### SUMMARY

In one embodiment, disclosed is a hydrofluoroolefin working fluid useful in immersion cooling comprising, a dielectric fluid selected from the group consisting of E-HFO-153-10mczz, E-HFO-153-10mzzy, and combinations thereof, and at least one of from about 10 ppm to about 145 ppm of water (dissolved in the dielectric fluid) and from about 10 to about 2000 ppm of a plasticizer or plasticizer mixture (dissolved in the dielectric fluid) and optionally other common contaminants. In spite of the presence of water and or plasticizers, the dielectric constant of the fluid remains below 2.0, and in another embodiment remains below 1.8. In one embodiment, the dissipation factor of the fluid at 20 GHz is less than 8.0E-03. In another embodiment, the dissipation factor of the fluid at 20 GHz is less than 2.5E-03.

In one embodiment, an immersion cooling unit including an immersion cell, defining an internal cavity, is provided. An electronic or electrical component is positioned in the internal cavity. A dielectric working fluid partially fills the internal cavity and at least partially immerses the heat generating electronic or electrical device. A condenser, such as a condensing coil, is positioned inside the cavity above the dielectric working fluid.

The dielectric working fluid comprises at least one of 1,1,1,2,2,5,5,6,6,6-decafluoro-3-hexene, (HFO-153-10mczz) and 1,1,1,4,5,5,5-heptafluoro-4-trifluoromethyl-2-pentene, (HFO-153-10mzzy) and at least one of from about 10 ppm to about 145 ppm of water and from about 10 to about 2000 ppm of a plasticizer or plasticizer mixture. In another embodiment, the working fluid consists essentially of at least one of 1,1,1,2,2,5,5,6,6,6-decafluoro-3-hexene, (HFO-153-10mczz) and 1,1,1,4,5,5,5-heptafluoro-4-trifluoromethyl-2-pentene, (HFO-153-10mzzy) and at least one of from about 10 ppm to about 145 ppm of water and from about 10 to about 2000 ppm of a plasticizer or plasticizer mixture.

Other features and advantages of the present invention will be apparent from the following more detailed description, taken in conjunction with the accompanying drawings which illustrate, by way of example, the principles of the invention.

### DETAILED DESCRIPTION

Large scale computer server systems can perform significant workloads and generate a large amount of heat during their operation. A significant portion of the heat is generated from their operation. Due in part to the amount of heat generated, these systems are typically mounted in stacked configurations with large internal cooling fans and heat dissipating fins. As the size and density of these systems increases the thermal challenges are even greater, and eventually outpace the ability for forced air systems.

Two-phase immersion cooling is an emerging cooling technology for the high-performance cooling market as applied to high performance server systems. It relies on the heat absorbed in the process of vaporizing a liquid immersion fluid to a gas. The fluids used in this application must meet certain requirements to be viable in use. For example, the boiling temperature of the fluid should be in the range between 30-75° C. Generally, this range accommodates maintaining the server components at a sufficiently cool temperature while allowing generated heat to be dissipated sufficiently to an external heat sink. Alternatively, the operating temperature of the server, and the immersion cooling system could be raised or lowered, by using an enclosed system and raising or lowering the pressure within the system to raise or lower the boiling point of a given fluid.

Single phase immersion cooling has a long history in computer server cooling. There is no phase change in single phase immersion cooling. Instead, the liquid warms as it circulates through the computer server and or heat exchanger, and then is circulated with a pump to a heat exchanger for cooling prior to returning to the server, thus transferring heat away from the computer server. Fluids used for single phase immersion cooling typically have similar requirements as those for two-phase immersion cooling, except that the boiling temperatures are typically higher than 30-75° C., to reduce loss by evaporation.

Provided is an immersion cooling system having an operating temperature range near ambient temperatures. Embodiments of the present disclosure, for example, in comparison to concepts failing to include one or more of the features disclosed herein, provide an immersion cooling system having fluids for thermal management which are environmentally friendly (i.e., have a low global warming potential (GWP) and low ozone depletion potential (ODP)).

Also provided is a method of immersion cooling wherein the device is a heat generating component, comprising at least partially immersing the heat generating component into the immersion cooling fluid in a liquid state, and transferring heat from the heat generating component using the immersion cooling fluid. Such devices include high-capacity energy storage devices, electrical or electronic components, mechanical components and optical components. Examples of devices of the present disclosure include, but are not limited to, microprocessors, wafers used to manufacture semiconductor devices, power control semiconductors, electrical distribution switch gear, full computer servers, power electronics and transformers, circuit boards, multi-chip modules, packaged and unpackaged semiconductor devices, lasers, fuel cells, electrochemical cells and energy storage devices such as batteries.

In certain embodiments, the devices can include electronic devices, such as processors, including microprocessors. Microprocessors typically have maximum operating temperatures that range from about 60 to about 100° C., so effective heat transfer is required in conditions of high processing power, i.e. high heat rejection rates. In other embodiments, the devices may include energy storage systems, such as batteries. When rapidly charged or discharged, batteries can reject a significant amount of heat that needs to be effectively removed to avoid overheating, internal damage, thermal runaway to adjacent batteries and potentially fire. As these electronic and electric devices become denser, and more powerful, the amount heat generated per unit of time and volume increases. Therefore, the mechanism of heat transfer plays an important role in processor or electronic/electrical component performance. The heat transfer fluid typically has good heat transfer performance, good electrical compatibility (even if used in “indirect contact” applications such as those employing cold plates), as well as low toxicity, low or nonflammability and low environmental impact. Good electrical compatibility suggests that the heat-transfer fluid candidate exhibit high dielectric strength, high volume resistivity, low dissipation factor, low dielectric constant. Additionally, the heat-transfer fluid should exhibit good material compatibility, that is, it should not affect typical materials of construction in an adverse manner.

It is generally understood that perfluorinated liquids such as Fluoroinert FC-72 and FC-3284 may exhibit excellent dielectric properties such as dielectric constants of 2.0 or less, high volume resistivity on the order of 10¹⁵ ohm·cm and high dielectric strength. However, these fluids are also generally associated with a high GWP, well outside the current requirements for many industrial applications. The GWP of Fluorinert FC-72 is reported to be >9000. Hydrofluoroethers (HFEs) have lower GWP's but are still not satisfactory and typically have poorer dielectric properties compared to FC-72 and FC-3284. Novec 7100 for example has a GWP of 297. Therefore, there continues to be a need for working fluids for immersion cooling that satisfy the dielectric applications of the industry while having a GWP below current requirements for the industry, which are typically less than 150. In another embodiment, the GWP of a working fluid is less than 100. In another embodiment, the compositions disclosed have a Global Warming Potential (GWP) of not greater than 50. As used herein, “GWP” is measured relative to that of carbon dioxide and over a 100-year time horizon, as defined in “The Scientific Assessment of Ozone Depletion, 2002, a report of the World Meteorological Association's Global Ozone Research and Monitoring Project,”.

It is highly desirable that the new fluids have equivalent or superior heat transfer properties, including electronic surface-to-fluid thermal resistance, critical heat flux and fluid-to-condenser thermal resistance, compared to higher GWP existing fluids such as FC-72, FC-3284, Novec-7100, Novec-7000 so that they can replace these fluids in existing systems without significant loss in thermal performance or mechanical modifications; and in new systems designed for FC-72, FC-3284, Novec-7100, without significant mechanical design changes. The practice of replacing an existing fluid with a new fluid in an existing system is often called “retrofit”.

It is also highly desirable that the new fluids provide at least minimum dielectric properties required by the application, or even superior dielectric properties compared to existing fluids such as such as FC-72, FC-3284, HFE-7100 so that they can replace these fluids in existing systems without significant electrical or mechanical modifications; and in new systems designed for FC-72, FC-3284, Novec-7100 without significant electrical or mechanical design changes. The desirable dielectric properties include high volume resistivity, low dielectric constant, high dielectric strength and low loss tangent.

It is also desirable that these fluids are compatible with the electrical components contained within the immersion cooling system. Being compatible includes not attacking or significantly swelling any of the electrical components, and not extracting anything from any of the computer components which would degrade or compromise the dielectric properties of the working fluids.

It is also desirable that these fluids have similar normal boiling points compared to high GWP fluids such as FC-72, FC-3284, Novec-7100, so that they can be used to replace these in existing systems without significant mechanical or operational changes and in new systems without significant mechanical design changes.

It is known that most existing high GWP fluids such as FC-72, FC-3284, and Novec 649 are not aggressive solvents towards most materials used in electronic applications, so that the elastomeric materials do not swell excessively. It is also true however that the typical plasticizer is readily extracted, although the solubility of most typical plasticizers is also rather low in these fluids.

This low solubility can lead to some fluids becoming saturated with plasticizer or a mixture of plasticizers. Plasticizers can include but are not limited to: tris-2-ethylhexyl trimellitate, dioctyl terephthalate, diisobutyl terephthalate, N-butyl benzene sulfonamide, diethylsuccinate, dimethylsuccinate, Di-isodecyl sebacate, Di-2-ethylhexyl sebacate, Dibutyl sebacate, Dibutyl sebacate, Hexanedioic acid polymer with 2,2-dimethyl-1,3-propanediol and 1,2-propanediol isononyl ester, Hexanedioic acid polymer with 1,2-propanediol octyl ester, Hexanedioic acid polymer with 1,2-propanediol, acetate, Tris(2-ethylhexyl)phosphate, 2-ethylhexyl diphenyl phosphate, Triphenyl phosphate, 2,2,4-trimethyl-1,3 pentanediol di-isobutyrate, Pentaerythritol ester of valeric acid (PETV), Alkylsulphonic acid ester with phenol (ASE), Di-C16-18 alkyl phthalate, Benzyl C7-9-branched and linear alkyl phthalate, Diisotridecyl phthalate, Diisoundecyl phthalate, Di(2-propyl heptyl) phthalate, Diisodecyl phthalate, Diisononyl phthalate, Bis(2-ethylhexyl) phthalate, Diisooctyl phthalate, Di-n-octyl phthalate, Diisoheptyl phthalate, Dicyclohexyl phthalate, Diisohexyl phthalate, Di-n-hexyl phthalate, Di-n-pentyl phthalate, Benzyl butyl phthalate, Diisobutyl phthalate, Di-n-butyl phthalate. Di-n-propyl phthalate, Diethyl phthalate, Dimethyl phthalate, Epoxidised soybean oil, Epoxidised linseed oil, Di-isononyl cyclohexane dicarboxylate, Acetyl tributyl citrate, Tributyl citrate, Triethyl citrate, Tri-ethylene glycol dibenzoate, Isodecyl benzoate, isononyl benzoate, dipropylene glychol dibenzoate, diethylene glycol dibenzoate, neopetnylglycol dibenzoate, diisodecyl azelate, Bis [2-(2-butoxyethoxy)ethyl]adipate, Di-(2-butoxyethyl) adipate, Di-n-butyl adipate, Ditridecyl adipate, Diisodecyl adipate, diisononyl adipate, Di-2-ethylhexyl adipate, Benzyl 2-ethylhexyl adipate, Diisobutyl adipate, Glyceryl triacetate. Contaminants other than plasticizers could include other extractables from thermal pastes, solder fluxes, and other process fluids originating from tank and server components, such as polydimethylsulfoxides.

During the operation of the immersion cooling system, as the electrical components generate heat in their operation, this heat is transferred to the dielectric fluids. Although there is some circulation and distribution of this heat due to convection, the dielectric fluid immediately adjacent to the components warms rapidly and reaches its boiling point and begins to boil. When this fluid boils at the component surface, as the liquid is flashed to vapor, any dissolved plasticizers of course are non-volatile at the fluid boiling point. If the dielectric fluid is at the saturation limit for plasticizer, this residual material is not able to be dissolved by remaining dielectric fluid, so it deposits on the available surface.

Once deposited on a surface, since the remaining fluid is saturated, it is not redissolved, but remains as a coating layer, which slowly builds up on the surface. Once deposited on the surface, this plasticizer or mixture of plasticizers coating becomes a growing heat transfer resistance which subsequently reduces cooling effectiveness from the device to the fluid.

Amounts of the vaporized dielectric fluid are condensed through heat exchange with a coolant flowing through the condenser.

Two new dielectric fluids have been identified which have excellent dielectric properties, and an appropriate boiling point to be an effective immersion cooling working fluid. These two fluids are 1,1,1,2,2,5,5,6,6,6-decafluoro-3-hexene, (HFO-153-10mczz) and 1,1,1,4,5,5,5-heptafluoro-4-trifluoromethyl-2-pentene, (HFO-153-10mzzy). It has now been found that the solubility of plasticizers, such as mentioned here, have significantly and unexpectedly higher solubility in the two new dielectric working fluids, HFO-153-10mczz and HFO-153-10mzzy, as show in Table 1. In one embodiment, the plasticizers are one or more of dioctyl terephthalate (DOTP), trioctyl trimellitate (TOTM), diisononylphthalate and diisodecylphthalate, dioctyl pthalate (DOP). Solubility data for two common plasticizers, dioctyl terephthalate and trioctyl trimellitate in HFO-153-10mczz and HFO-153-10mzzy, as well as Novec 649 and FC-72 are shown below in Table 1.

TABLE 1
Solubility of DOTP and TOTM in dielectric fluids

| Dielectric Fluid | Solubility DOTP (ppm) | Solubility TOTM (ppm) |
|---|---|---|
| HFO-153-10mczz | 7000 | 2700 |
| HFO-153-10mzyy | 7300 | At least 1000 |
| Novec 649 | 44 | 40 |
| FC-72 | 46 | 10 |

Similarly, it has been observed that the solubility of water is significantly higher in HFC-153-10mczz than in either Novec 649 or FC-72. Solubility data is summarized in Table 2, below.

TABLE 2
Solubility of water in Dielectric fluids.

| Dielectric Fluid | Water solubility at 20 C. |
|---|---|
| HFO-153-10mczz | 146 ppm |
| Novec 649 | 10 ppm |
| FC-72 | 20 ppm |

It has also been observed that the presence of either plasticizer or a mixture of plasticizers or water surprisingly does not have a significant deleterious effect on the dielectric properties of HFO-153-10mczz of HFO-153-10mzzy as well. Dielectric constant data and dissipation factor data for HFO-153-10mczz, and Novec 649 for comparison are shown in Table 3 below.

TABLE 3
Experimental dielectric properties for HFO-153-10mczz with contaminants

| | Dielectric Constant | | | Dissipation Factor | | |
|---|---|---|---|---|---|---|
| | 1 GHz | 14 GHz | 20 GHz | 1 GHz | 14 GHz | 20 GHz |
| HFO-153-10MCZZ (neat | 1.74 | 1.74 | 1.74 | 7.6E−04 | 7.9E−04 | 7.9E−04 |
| and dry) | | | | | | |
| HFO-153-10MCZZ with | 1.75 | 1.74 | 1.74 | 1.9E−03 | 2.0E−03 | 2.0E−03 |
| 50% water sat (72 ppm) | | | | | | |
| HFO-153-10MCZZ with | 1.75 | 1.74 | 1.74 | 2.0E−03 | 2.1E−03 | 2.1E−03 |
| 100% water sat (145 ppm) | | | | | | |
| HFO-153-10MCZZ Dry, | 1.75 | 1.74 | 1.74 | 2.0E−03 | 2.2E−03 | 2.2E−03 |
| with 100 ppm DOTP | | | | | | |
| Novec 649 (neat and dry) | 1.72 | 1.70 | 1.70 | 8.3E−03 | 8.9E−03 | 9.0E−03 |

As the data illustrate, the dielectric constant for HFO-153-10mczz with either 72 or 146 ppm of water, or 100 ppm of plasticizer is unchanged, and is 1.74 to 1.75, depending on the frequency. In one embodiment, the dielectric constant is less than 2.0. In another embodiment, the dielectric constant is less than 1.8. The dissipation factor is seen to be only slightly higher than pure material, and in any case is still lower than neat and dry Novec 649. Even with either water saturation, or 100 ppm of DOTP, the dissipation factor for HFO-153-10mczz is found to be 2.2E-03 or lower at 20 GHz. In another embodiment, the dissipation factor for HFO-153-10mczz is 2.0E-03 at 20 GHz. In another embodiment, the dissipation factor for HFO-153-10mczz is 8.0E-03 at 20 GHz.

It is also known that Novec 649 can be very sensitive to the presence of water and other contaminants resulting in degradation of the fluid and production of corrosive acids that can damage electronics and electrical components. The inventors have discovered that HFO-153-10mczz and HFO-153-10mzzy are, on the other hand, surprisingly inert to water and other contaminants under use conditions. Table 4 show results of a sealed tube thermal/chemical stability testing of immersion fluids Novec 649 and HFO-153-10mczz mixed with plasticizer TOTM and DOTP at a 50/50 mass ratio, 240 mmHg of air and different amounts of water up to above the water solubility limit of the immersion fluid. In addition, metal coupons of copper, aluminum and carbon steel were placed inside the sealed tube and immersed in the liquid mixture of the immersion fluid and contaminants. The sealed tubes were placed in an oven at a temperature of 150° C. for one week. After this period, the fluid mixture was analyzed for fluoride and acidity, which indicates fluid breakdown. One can see in Table 4 that for all water concentrations, HFO-153-10mczz surprisingly does not show any fluoride or acidity beyond the minimum detection level of 0.2 ppm and <1 ppm eqv. HCl, respectively. Novec 649, however, show very high levels of both fluoride and acidity for all water concentrations.

| | | | | | | Results of chemical | |
|---|---|---|---|---|---|---|---|
| | | | | | | analysis after 1 | |
| | Fluid and contaminants conditions | | | | | week exposure | |
| Seal | | | | | % water | | Acidity |
| tube | | Air | Plasticizer | Water | saturation | Fluoride | (ppm eqv. |
| # | Fluid | (mmHg) | (PPM) | (ppm) | at 20° C. | (ppm) | HCl) |
| 1 | HFO-153- | 240 | 100 | 20 | 14% | <0.2 | <1 |
| 2 | 10mczz | 240 | 100 | 60 | 41% | <0.2 | <1 |
| 3 | | 240 | 100 | 145 | 100% | <0.2 | <1 |
| 4 | | 240 | 100 | 290 | 200% | <0.2 | <1 |
| 5 | Novec | 240 | 100 | 10 | 50% | 42 | 342 |
| 6 | 649 | 240 | 100 | 20 | 100% | 40 | 367 |
| 7 | | 240 | 100 | 50 | 250% | 113 | 1041 |

Embodiments of the disclosed subject matter are useful in the immersion cooling unit described as follows. An immersion cooling unit is provided that includes an immersion cell which defines an internal cavity. An electrical component is disposed within the internal cavity and is immersed in a hydrofluoroolefin working fluid that partially fills the internal cavity. A condenser is also positioned in the internal cavity above the hydroolefin working fluid that is adapted and configured to condense amounts of vaporized hydroolefin working fluid (vaporized through generation of heat by the electrical component) via heat exchange with a cooling fluid flowing through the condenser. The dielectric working fluid is a hydrofluoroolefin working fluid that is useful in immersion cooling electrical components and which includes: a) a dielectric fluid selected from E-HFO-153-10mczz, E-HFO-153-10mzzy, or a combination of E-HFO-153-10mczz and E-HFO-153-10mzzy; and b) at least one of water and a plasticizer or plasticizer mixture dissolved in the dielectric fluid.

An immersion cooling process may be performed according to the following steps. The immersion cooling unit described above is provided. The electrical component is allowed to generate heat, thereby vaporizing amounts of the dielectric working fluid. Amounts of the vaporized dielectric fluid are condensed through heat exchange with the coolant flowing through the condenser.

An additional step of the above-described immersion cooling process may be performed as follows. For a period of time, the electrical component is allowed to generate heat and amounts of the vaporized dielectric fluid are condensed. Upon expiration of the period of time, the dissolved water, if present in said hydrofluoroolefin working fluid, is at a concentration of from about 10 ppm to about 145 ppm and the dissolved plasticizer or plasticizer mixture, if present in said hydrofluoroolefin working fluid, is at a concentration of from about 10 to about 7341 ppm.

### Additional Embodiments

A1. A hydrofluoroolefin working fluid useful in immersion cooling, comprising:
   a dielectric fluid selected from the group consisting of E-HFO-153-10mczz, E-HFO-153-10mzzy, and combinations thereof; and
   at least one of water and a plasticizer or plasticizer mixture dissolved in the dielectric fluid.
A2. A hydrofluoroolefin working fluid useful in immersion cooling, comprising:
   a dielectric fluid consisting of E-HFO-153-10mczz; and
   at least one of water and a plasticizer or plasticizer mixture dissolved in the dielectric fluid.
A3. A hydrofluoroolefin working fluid useful in immersion cooling, consisting essentially of:
   a dielectric fluid consisting of E-HFO-153-10mczz; and
   at least one of water and a plasticizer or plasticizer mixture dissolved in the dielectric fluid.
A4. A hydrofluoroolefin working fluid useful in immersion cooling, comprising:
   a dielectric fluid consisting of E-HFO-153-10mzzy; and
   at least one of water and a plasticizer or plasticizer mixture dissolved in the dielectric fluid.
A5. A hydrofluoroolefin working fluid useful in immersion cooling, consisting essentially of:
   a dielectric fluid consisting of E-HFO-153-10mzzy; and
   at least one of water and a plasticizer or plasticizer mixture dissolved in the dielectric fluid.
A6. A hydrofluoroolefin working fluid useful in immersion cooling, consisting essentially of:
   a dielectric fluid selected from E-HFO-153-10mczz and/or E-HFO-153-10mzzy; and
   at least one of water and a plasticizer or plasticizer mixture dissolved in the dielectric fluid.
A7. The hydrofluoroolefin working fluid of any one of embodiments A1-A6, wherein said dissolved plasticizer or plasticizer mixture is present in said working fluid and is one or more of bis(2-ethylhexyl) terephthalate, tris(2-ethylhexyl)trimellitate, diisononylphthalate, diisodecylphthalate, and bis-2-ethylhexylphthalate.
A8. The hydrofluoroolefin working fluid of any one of embodiments A1-A7, wherein said dissolved plasticizer or plasticizer mixture is present in said working fluid and is at a concentration of from about 10 to about 7341 ppm.
A9. The hydrofluoroolefin working fluid of any one of embodiments A1-A8, wherein said dissolved plasticizer or plasticizer mixture is present in said working fluid and is at a concentration of about 10 to about 7000 ppm.
A10. The hydrofluoroolefin working fluid of any one of embodiments A1-A9, wherein said dissolved plasticizer or plasticizer mixture is present in said working fluid and is at a concentration of about 10 to about 6000 ppm.
A11. The hydrofluoroolefin working fluid of any one of embodiments A1-A10, wherein said dissolved plasticizer or plasticizer mixture is present in said working fluid and is at a concentration of about 10 to about 5000 ppm.
A12. The hydrofluoroolefin working fluid of any one of embodiments A1-A11, wherein said dissolved plasticizer or plasticizer mixture is present in said working fluid and is at a concentration of about 10 to about 4000 ppm.
A13. The hydrofluoroolefin working fluid of any one of embodiments A1-A12, wherein said dissolved plasticizer or plasticizer mixture is present in said working fluid and is at a concentration of about 10 to about 3000 ppm.
A14. The hydrofluoroolefin working fluid of any one of embodiments A1-A13, wherein said dissolved plasticizer or plasticizer mixture is present in said working fluid and is at a concentration of about 10 to about 2000 ppm.
A15. The hydrofluoroolefin working fluid of any one of embodiments A1-A14, wherein said dissolved plasticizer or plasticizer mixture is present in said working fluid and is at a concentration of about 10 to about 1000 ppm.
A16. The hydrofluoroolefin working fluid of any one of embodiments A1-A15, wherein said dissolved plasticizer or plasticizer mixture is present in said working fluid and is at a concentration of about 10 to about 500 ppm.
A17. The hydrofluoroolefin working fluid of any one of embodiments A1-A16, wherein said dissolved plasticizer or plasticizer mixture is present in said working fluid and is at a concentration of about 10 to about 250 ppm.
A18. The hydrofluoroolefin working fluid of any one of embodiments A1-A17, wherein said dissolved plasticizer or plasticizer mixture is present in said working fluid and is at a concentration of about 10 to about 100 ppm.
A19. The hydrofluoroolefin working fluid of any one of embodiments A1-A18, wherein said dissolved plasticizer or plasticizer mixture is present in said working fluid and is at a concentration of greater than 46 ppm to about 7341 ppm.
A20. The hydrofluoroolefin working fluid of any one of embodiments A1-A19, wherein said dissolved plasticizer or plasticizer mixture is present in said working fluid and is at a concentration of greater than 46 ppm to about 7000 ppm.
A21. The hydrofluoroolefin working fluid of any one of embodiments A1-A20, wherein said dissolved plasticizer or plasticizer mixture is present in said working fluid and is at a concentration of greater than 46 ppm to about 6000 ppm.
A22. The hydrofluoroolefin working fluid of any one of embodiments A1-A21, wherein said dissolved plasticizer or plasticizer mixture is present in said working fluid and is at a concentration of greater than 46 ppm to about 5000 ppm.
A23. The hydrofluoroolefin working fluid of any one of embodiments A1-A22, wherein said dissolved plasticizer or plasticizer mixture is present in said working fluid and is at a concentration of greater than 46 ppm to about 4000 ppm.
A24. The hydrofluoroolefin working fluid of any one of embodiments A1-A23, wherein said dissolved plasticizer or plasticizer mixture is present in said working fluid and is at a concentration of greater than 46 ppm to about 3000 ppm.
A25. The hydrofluoroolefin working fluid of any one of embodiments A1-A24, wherein said dissolved plasticizer or plasticizer mixture is present in said working fluid and is at a concentration of greater than 46 ppm to about 2000 ppm.
A26. The hydrofluoroolefin working fluid of any one of embodiments A1-A25, wherein said dissolved plasticizer or plasticizer mixture is present in said working fluid and is at a concentration of greater than 46 ppm to about 1000 ppm.
A27. The hydrofluoroolefin working fluid of any one of embodiments A1-A26, wherein said dissolved plasticizer or plasticizer mixture is present in said working fluid and is at a concentration of greater than 46 ppm to about 500 ppm.
A28. The hydrofluoroolefin working fluid of any one of embodiments A1-A27, wherein said dissolved plasticizer or plasticizer mixture is present in said working fluid and is at a concentration of greater than 46 ppm to about 250 ppm.
A29. The hydrofluoroolefin working fluid of any one of embodiments A1-A28, wherein said dissolved plasticizer or plasticizer mixture is present in said working fluid and is at a concentration of greater than 46 ppm to about 100 ppm.
A30. The hydrofluoroolefin working fluid of any one of embodiments A1-A29, wherein said dissolved water is present in said working fluid and is at a concentration of greater than 10 ppm to about 145 ppm.
A31. The hydrofluoroolefin working fluid of any one of embodiments A1-A30, wherein said dissolved water is present in said working fluid and is at a concentration of greater than 10 ppm to about 100 ppm.
A32. The hydrofluoroolefin working fluid of any one of embodiments A1-A31, wherein said dissolved water is present in said working fluid and is at a concentration of greater than 10 ppm to about 75 ppm.
A33. The hydrofluoroolefin working fluid of any one of embodiments A1-A32, wherein said dissolved water is present in said working fluid and is at a concentration of greater than 10 ppm to about 50 ppm.
A34. The hydrofluoroolefin working fluid of any one of embodiments A1-A33, wherein said dissolved water is present in said working fluid and is at a concentration of greater than 20 ppm to about 145 ppm.
A35. The hydrofluoroolefin working fluid of any one of embodiments A1-A34, wherein said dissolved water is present in said working fluid and is at a concentration of greater than 20 ppm to about 100 ppm.
A36. The hydrofluoroolefin working fluid of any one of embodiments A1-A35, wherein said dissolved water is present in said working fluid and is at a concentration of greater than 20 ppm to about 75 ppm.
A37. The hydrofluoroolefin working fluid of any one of embodiments A1-A36, wherein said dissolved water is present in said working fluid and is at a concentration of greater than 20 ppm to about 50 ppm.
A38. The hydrofluoroolefin working fluid of any one of embodiments A1-A37, wherein a dielectric constant of the working fluid is less than about 2.0.
A39. The hydrofluoroolefin working fluid of any one of embodiments A1-A38, wherein a dielectric constant of the working fluid is less than about 1.8.
A40. The hydrofluoroolefin working fluid of any one of embodiments A1-A39, wherein the working fluid has a dissipation factor at 20 GHz of less than about 8.0E-03.
A41. The hydrofluoroolefin working fluid of any one of embodiments A1-A40, wherein the working fluid has a dissipation factor at 20 GHz of less than about 2.5E-03.
A42. An immersion cooling unit comprising:
   an immersion cell, defining an internal cavity;
   an electrical component in the internal cavity;
   a hydrofluoroolefin working fluid partially filling the internal cavity and in which the electrical component is at least partially immersed; and
   a condenser, positioned in the internal cavity above the hydrofluoroolefin working fluid, that is adapted and configured to condense amounts of the hydrofluoroolefin working fluid that may be vaporized through generation of heat by said electrical component, wherein the hydrofluoroolefin working fluid is the hydrofluoroolefin working fluid of any of embodiments A1-A41.
A43. An immersion cooling process, comprising the steps of:
   providing the immersion cooling unit of embodiment A42;
   allowing the electrical component to generate heat, thereby vaporizing amounts of the dielectric fluid; and
   condensing amounts of the vaporized dielectric fluid through heat exchange with a coolant flowing through the condenser.
A44. The immersion cooling process of embodiment A43, further comprising a step of allowing each of said steps of allowing the electrical component to generate heat and condensing amounts of the vaporized dielectric fluid to be performed for a period of time, wherein upon expiration of the period of time, the dissolved water, if present in said hydrofluoroolefin working fluid, is at a concentration of from about 10 ppm to about 145 ppm and the dissolved plasticizer or plasticizer mixture, if present in said hydrofluoroolefin working fluid, is at a concentration of from about 10 to about 7341 ppm.

1. A hydrofluoroolefin working fluid useful in immersion cooling, comprising:
a dielectric fluid selected from the group consisting of E-HFO-153-10mczz, E-HFO-153-10mzzy, and combinations thereof; and
at least one of water and a plasticizer or plasticizer mixture dissolved within the dielectric fluid, wherein the dissolved water, if present, is at a concentration of from about 10 ppm to about 145 ppm and the dissolved plasticizer or plasticizer mixture, if present, is at a concentration of from about 10 to about 7341 ppm.

2. The hydrofluoroolefin working fluid of claim 1, wherein the dielectric fluid consists of E-HFO-153-10mczz.

3. (canceled)

3. The hydrofluoroolefin working fluid of claim 1, wherein the dissolved plasticizer or plasticizer mixture is present in said working fluid and is one or more of bis(2-ethylhexyl) terephthalate, tris(2-ethylhexyl)trimellitate, diisononylphthalate, diisodecylphthalate, and bis-2-ethylhexylphthalate.

4. (canceled)

4. The hydrofluoroolefin working fluid of claim 1, wherein said dissolved plasticizer or plasticizer mixture is present in said working fluid and is at a concentration of about 10 to about 2000 ppm.

5. (canceled)

5. The hydrofluoroolefin working fluid of claim 1, wherein said dissolved plasticizer or plasticizer mixture is present in said working fluid and is at a concentration of about 10 to about 1000 ppm.

6. (canceled)

6. The hydrofluoroolefin working fluid of claim 1, wherein said dissolved water is present in said working fluid and is at a concentration of from about 10 ppm to about 100 ppm.

7. The hydrofluoroolefin working fluid of claim 1, wherein said dissolved plasticizer or plasticizer mixture is present in said working fluid and is at a concentration of about 10 to about 50 ppm.

8. The hydrofluoroolefin working fluid of claim 1, wherein a dielectric constant of the working fluid is less than about 2.0.

9. The hydrofluoroolefin working fluid of claim 1, wherein a dielectric constant of the working fluid is less than about 1.8.

10. The hydrofluoroolefin working fluid of claim 1, wherein the working fluid has a dissipation factor at 20 GHz of less than about 8.0E-03.

11. The hydrofluoroolefin working fluid of claim 1, wherein the working fluid has a dissipation factor at 20 GHz of less than about 2.5E-03.

12. An immersion cooling unit comprising:
an immersion cell, defining an internal cavity;
an electrical component in the internal cavity;
a working fluid partially filling the internal cavity; and
a condenser positioned in the internal cavity above the working fluid, wherein the working fluid at least partially immerses the electrical component and the working fluid is the hydrofluoroolefin working fluid of claim 1.
